(19) United States
(12) Patent Application Publication
(10) Pub. No.: US 2022/0200181 A1
(43) Pub. Date: Jun. 23, 2022

(54) CONNECTOR ASSEMBLY, SYSTEM AND LITHOGRAPHY INSTALLATION

(71) Applicant: Carl Zeiss SMT GmbH, Oberkochen (DE)

(72) Inventor: Thomas Wolfsteiner, Aalen (DE)

(21) Appl. No.: 17/695,036

(22) Filed: Mar. 15, 2022

Related U.S. Application Data
(63) Continuation of application No. PCT/EP2020/073997, filed on Aug. 27, 2020.

(30) Foreign Application Priority Data
Sep. 16, 2019 (DE) 102019214050.5

(51) Int. Cl. H01R 12/91; G03F 7/20; H01R 12/71

(52) U.S. Cl. CPC H01R 12/91; H01R 12/716; G03F 7/70808

(57) ABSTRACT

A connector arrangement includes a first connector element, a second connector element, a first printed circuit board section and a second printed circuit board section. The second connector element can be plugged together with the first connector element in an insertion direction to form an electrical connection. The first connector is mounted on the first printed circuit board section. The first printed circuit board section is mounted on the second printed circuit board section such that the first printed circuit board section is movable perpendicularly to the insertion direction. This can bring about tolerance compensation when the first and second connector elements are plugged together.

### CROSS-REFERENCE TO RELATED APPLICATIONS

The present application is a continuation of, and claims benefit under 35 USC 120 to, international application PCT/EP2020/073997, filed Aug. 27, 2020, which claims benefit under 35 USC 119 of German Application No. 10 2019 214 050.5, filed Sep. 16, 2019. The entire disclosure of these applications are incorporated by reference herein.

### FIELD

The present disclosure relates to a connector arrangement, to a system, and to a lithography apparatus having such a connector arrangement and/or such a system.

### BACKGROUND

Microlithography is used for producing microstructured components, such as for example integrated circuits. The microlithography process is performed using a lithography apparatus, which has an illumination system and a projection system. The image of a mask (reticle) illuminated using the illumination system is in this case projected using the projection system onto a substrate, for example a silicon wafer, which is coated with a light-sensitive layer (photoresist) and arranged in the image plane of the projection system, in order to transfer the mask structure to the light-sensitive coating of the substrate.

Lithography apparatuses can include a multiplicity of actuators and sensors that, as an assembly, are brought into electrical contact with other assemblies of the lithography apparatus. Due to limited installation space, the use of cables that are brought into contact by hand, for example, can be difficult. Furthermore, it can be difficult to connect a plurality of connectors which are provided on a printed circuit board with corresponding mating connectors which are provided on another printed circuit board, due to manufacturing tolerances.

In order to electrically connect two assemblies of a lithography apparatus to one another, it is known to use connectors that bring about tolerance compensation. In this respect, there are connectors that include spring contact pins and bring about tolerance compensation in the insertion direction. Furthermore, sockets are known which are mounted using spring elements and bring about tolerance compensation perpendicularly to the insertion direction. The sockets are supported on a printed circuit board via the spring elements.

### SUMMARY

The present disclosure seeks to provide an improved connector arrangement.

Accordingly, a connector arrangement, for example for a lithography apparatus, is proposed. The connector arrangement includes a first connector element, a second connector element, which can be plugged together with the first connector element in an insertion direction to form an electrical connection, a carrier element, which carries the first connector element, and a receptacle, in which the carrier element is accommodated so as to be movable perpendicularly to the insertion direction in order to bring about tolerance compensation when plugging together the first and second connector elements.

As a result, the connector elements do not necessarily have to bring about tolerance compensation perpendicularly to the insertion direction, since the carrier element brings about tolerance compensation in the receptacle. Furthermore, there can be the advantage that less complex connector elements can be used. An alternative to tolerance-compensating connectors can be provided in this way. In addition, there can be the advantage that greater tolerance compensation can be brought about with the movable carrier element, since narrower limits are set in this respect in the case of the tolerance-compensating connector.

The movability is realized for example by a floating support. The first connector element can be a connector and the second connector element can be an associated mating connector. This forms a connector pair. The carrier element is provided so as to be movable in a first movement direction, which runs perpendicularly to the insertion direction. The carrier element can have a two-dimensional form and can have a thickness of between 1.5 and 4 mm, for example 2 and 3 mm.

For example, the first connector element can be connected fixedly to the carrier element with a materially bonded connection, for example via an adhesive bond, or with a form-fitting connection, for example via a plug-in connection. The carrier element can also be provided so as to be movable in a second movement direction, which runs perpendicularly to the insertion direction and perpendicularly to the first movement direction. Accommodated in the carrier element means that the receptacle spatially encloses the carrier element at least partially. The receptacle can enclose a cavity that is larger than the carrier element so as to accommodate the carrier element therein. The carrier element and the receptacle can be configured to bring about a tolerance compensation of between 0.1-10 mm in the first movement direction. Furthermore, an opening to the cavity can be formed. Viewed from the opening, the cavity can include at least one undercut. The connector arrangement can include 2, 3 or 4 carrier elements, which are accommodated in receptacles so as to be movable perpendicularly to the insertion direction.

According to an embodiment, the carrier element is a printed circuit board.

The printed circuit board can be referred to as a PCB and can include conductor tracks. Optionally, the printed circuit board can furthermore include a fiber-reinforced plastic (FRP), which can form a support structure for the conductor tracks. For example, the printed circuit board can include ceramics or be formed as a ceramic printed circuit board. The printed circuit board can, for example, be a carrier of further electrical components. For example, all carrier elements can be formed as printed circuit boards.

According to an embodiment, the carrier element is accommodated in the receptacle in such a way that a gap is provided perpendicular to the insertion direction, which gap defines and delimits the movability perpendicularly to the insertion direction.

For example, the gap can be an air gap. The carrier element can rest against a support surface of the connector arrangement and is provided so as to be freely movable thereon, wherein friction between the carrier element and the support surface is overcome for the movement to take place. The gap can be variable for example due to the movability of the carrier element. For example, a maximum gap (i.e., when the carrier element rests against a side wall of the receptacle) can be between 0.1 and 15 mm, for example 1 and 5 mm. Optionally, a clearance is provided viewed in the insertion direction between the carrier element, for example between an upper side of the carrier element, and the receptacle in order to ensure free movability of the carrier element in the receptacle. The clearance can be between 0.05 and 2 mm, for example between 0.1 and 1.5 mm. This prevents the carrier element from becoming jammed in the receptacle.

According to an embodiment, the gap is formed as an annular gap which surrounds the carrier element.

This can have the advantage that it is made possible for the carrier element to move in all directions in one plane. The annular gap can have a closed annular shape. Annular shape means a shape that can have angular and/or round contours. The annular gap can, for example, have a frame shape when viewed in or counter to the insertion direction. For example, a width of the annular gap is 0.05-7.5 mm, for example 0.5 and 2.5 mm, when the carrier element is aligned centrally in the receptacle.

According to an embodiment, the connector arrangement has a first housing element in which the receptacle is provided and/or a second housing element to which the second connector element is connected.

For example, the first and second housing elements may each be formed as a housing. The second connector element can be connected to the second housing element with a materially bonded connection (e.g. via an adhesive bond) and/or with a form-fitting connection.

According to an embodiment, the connector arrangement has a first centering element, which is directly or indirectly rigidly connected to the carrier element, and a second centering element, which is provided on the second housing element, wherein the first and the second centering element interact in such a way that the first connector element and the second connector element are centered relative to one another, for example with a precise fit, when they are plugged together in the insertion direction.

This can have the advantage that the first connector element and the second connector element find each other reliably when the housing elements are moved toward one another in the insertion direction. For example, the carrier element and the first centering element can be connected to one another with a materially bonded connection, for example via an adhesive bond, and/or with a form-fitting connection. Alternatively, these can be formed integrally. The first centering element can be in the form of a pin. Optionally, the first centering element and/or the second centering element can include an insertion bevel and/or a tip for causing a centering effect. Pre-centering can take place with the aid of the first and second centering elements, and final centering can take place with the aid of the first and second connector elements.

According to an embodiment, the first centering element is provided next to the first connector element, extends beyond the first connector element in the insertion direction, and is directly or indirectly rigidly connected to the first connector element, wherein the second centering element includes a receiving element, which is configured to accommodate the first centering element for the purpose of causing the centering.

The first centering element and the second centering element can be provided in a rotationally symmetric manner, at least partially. This can have the advantage that a centering effect can be effected in all directions in one plane. For example, the receiving element can include a cavity for accommodating the first centering element. The first centering element can, for example, be directly connected to the first connector element or provided so as to be in contact therewith. Alternatively, the first centering element and the first connector element can be connected to the carrier element at a distance from one another.

According to an embodiment, the connector arrangement has a third connector element, a fourth connector element, which can be plugged together with the third connector element in the insertion direction to form an electrical connection, a further carrier element, which carries the third connector element, and a further receptacle, in which the further carrier element is accommodated so as to be movable perpendicularly to the insertion direction in order to bring about tolerance compensation when the third and fourth connector elements are plugged together, wherein the further receptacle is provided in the first housing element, and wherein the fourth connector element is connected to the second housing element.

The third and fourth connector elements can be formed as a connector and an associated mating connector. For example, a third centering element can be directly or indirectly rigidly connected to the further carrier element. A fourth centering element can be provided on the second housing element, wherein the third and the fourth centering element can interact in such a way that the third connector element and the fourth connector element are aligned with one another with a precise fit when they are plugged together in the insertion direction. The third centering element and the fourth centering element can be formed identically to the first and second centering elements.

This can have the advantage that, when the first and second housing elements are brought together, two carrier elements independently bring about tolerance compensation, and so two connector pairs can be reliably connected to one another. There can also be three, four or more carrier elements and corresponding connector pairs and interacting centering elements with the first and second housing elements. The carrier elements can be electrically connected to one another via flexible cables. For example, the carrier elements can be connected to one another via a rigid-flex connection. For example, a plurality of carrier elements can be formed as a rigid-flex-rigid printed circuit board.

According to an embodiment, one of the first connector element and the second connector element includes a 10-400, for example 80-300, pin connector and the other of the first connector element and the second connector element includes a 10-400 pin socket, for example an 80-300 pin socket.

Optionally, the first or second connector element includes pins which include insertion bevels which are adapted to interact with opening edges of associated sockets so as to effect centering.

In addition, a connector arrangement, for example for a lithography apparatus, is proposed. The connector arrangement can include a first connector element, a second connector element, which can be plugged together with the first connector element in an insertion direction to form an electrical connection, a first printed circuit board section, on which the first connector element is mounted, and a second printed circuit board section, in which the first printed circuit board section is mounted so as to be movable perpendicularly to the insertion direction in order to bring about tolerance compensation when the first and second connector elements are plugged together.

An alternative to tolerance-compensating connectors can thus be provided by virtue of the fact that printed circuit board sections bring about tolerance compensation perpendicularly to the insertion direction when two connector elements are plugged together. The first and the second printed circuit board section can have the same thickness. The first and the second printed circuit board section can form a printed circuit board. For example, the second printed circuit board section can surround the first printed circuit board section in the form of a frame. Spring elements can be provided between the first and second printed circuit board sections. For example, a gap can be formed between the first and the second printed circuit board section. For example, a maximum movement between the first printed circuit board section and the second printed circuit board section can be between 0.1 and 15 mm, for example 1 and 5 mm.

According to an embodiment, the first printed circuit board section and the second printed circuit board section are formed integrally with one another.

For example, the first printed circuit board section and the second printed circuit board section can be separated from one another only via material weakenings, e.g. cutouts, in the printed circuit board.

According to an embodiment, the connector arrangement includes at least one flexure, wherein the first printed circuit board section and the second printed circuit board section are connected to one another via the at least one flexure.

A flexure refers to a component that allows a relative movement between the printed circuit board sections and is deformed, for example elastically, in the process. The two printed circuit board sections can be connected to one another via 1, 2, 3, 4, 5 or more flexures. The flexure can provided be, for example, integrally with the two printed circuit board sections. The flexure can be formed as the spring element.

The embodiments and features described for the alternative connector arrangements apply correspondingly to both alternatives. Furthermore, the features described for the carrier element apply correspondingly to the first printed circuit board section and vice versa. In addition, the features described for an element with the same name, e.g. carrier element, connector element, centering element, receptacle, etc., apply correspondingly to all others and vice versa.

A system, for example for a lithography apparatus, is also proposed. The system can include a connector arrangement, as described above, an actuator, and/or a sensor, which is electrically connected to the carrier section or the second printed circuit board section and the first connector element, wherein the first connector element for example forms an electronic interface of the actuator and/or a sensor, which interface is connectable to the second connector element.

The system can include 2, 3 or 4 actuators, wherein the first connector element forms an electronic interface of one or all of the actuators. For example, the system can include 2, 3, 4, 5 or more sensors, wherein the first connector element forms an electronic interface of one or all of the sensors. For example, one connector element can be provided as an electronic interface for each sensor or actuator. The actuator can be connected to the first housing element, for example by screws.

According to an embodiment, the system includes an integrated circuit, which is electrically connected to the second connector element, wherein the second connector element for example forms an electronic interface of the integrated circuit to the first connector element.

The integrated circuit can be, for example, an FPGA (field programmable gate array). The integrated circuit can include for example a processor. The integrated circuit can be configured to carry out computing operations for the actuator or actuators or sensors. The integrated circuit can for example be provided on a printed circuit board which is connected, for example by screws, to the second housing element.

The embodiments and features described for the system apply correspondingly to the connector arrangement and vice versa.

Furthermore, a lithography apparatus is proposed. The lithography apparatus can include a connector arrangement as described above and/or a system as described above.

“A(n); one” in the present case should not necessarily be understood to be restrictive to exactly one element. Rather, a plurality of elements, such as, for example, two, three or more, can also be provided. Any other numeral used here, too, should not be understood to the effect that there is a restriction to exactly the stated number of elements. Rather, numerical deviations upwards and downwards are possible, unless indicated to the contrary.

Further possible implementations of the disclosure also include not explicitly mentioned combinations of any features or embodiments that are described above or below with respect to the exemplary embodiments. In this case, a person skilled in the art will also add individual aspects as improvements or supplementations to the respective basic form of the disclosure.

Further refinements and aspects of the disclosure are the subject matter of the claims and also of the exemplary embodiments of the disclosure described below.

### BRIEF DESCRIPTION OF THE DRAWINGS

In the text that follows, the disclosure will be explained in more detail on the basis of embodiments with reference to the accompanying figures.

FIG. 1A shows a schematic view of an embodiment of an EUV lithography apparatus;

FIG. 1B shows a schematic view of an embodiment of a DUV lithography apparatus;

FIG. 2 shows a schematic view of a connector arrangement;

FIG. 3 shows section from FIG. 2;

FIG. 4 shows a schematic perspective view of an embodiment of the connector arrangement;

FIG. 5 shows section V-V from FIG. 4;

FIG. 6 shows a further view of section V-V from FIG. 4;

FIG. 7 shows a further view of section V-V from FIG. 4;

FIG. 8 shows a schematic perspective sectional view of an embodiment of the connector arrangement;

FIG. 9 shows a schematic view of an embodiment of the connector arrangement;

FIG. 10 shows a schematic top view of a printed circuit board;

FIG. 11 shows a schematic view of an embodiment of a system; and

FIG. 12 shows a schematic view of an embodiment of the system.

### DESCRIPTION OF EXEMPLARY EMBODIMENTS

Unless indicated to the contrary, elements that are the same or functionally the same have been provided with the same reference signs in the figures. It should also be noted that the illustrations in the figures are not necessarily true to scale.

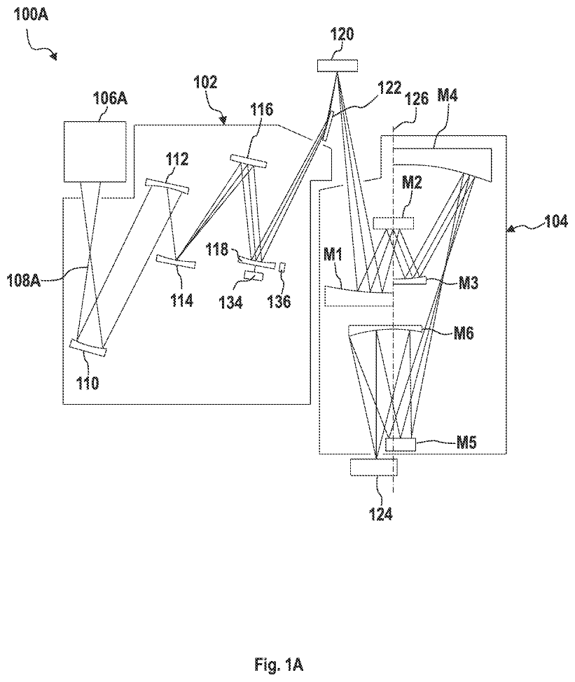

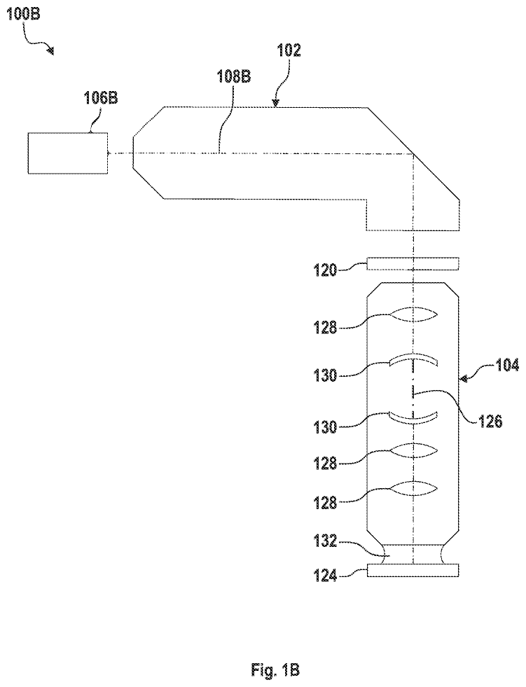

FIG. 1A shows a schematic view of an EUV lithography apparatus 100A including a beam-shaping and illumination system 102 and a projection system 104. In this case, EUV stands for “extreme ultraviolet” and denotes a wavelength of the working light of between 0.1 nm and 30 nm. The beam-shaping and illumination system 102 and the projection system 104 are respectively provided in a vacuum housing (not shown), wherein each vacuum housing is evacuated with the aid of an evacuation apparatus (not shown). The vacuum housings are surrounded by a machine room (not shown), in which drive apparatuses for mechanically moving or setting optical elements are provided. Furthermore, electrical controllers and the like may also be provided in the machine room.

The EUV lithography apparatus 100A has an EUV light source 106A. A plasma source (or a synchrotron), which emits radiation 108A in the EUV range (extreme ultraviolet range), that is to say for example in the wavelength range of 5 nm to 20 nm, can for example be provided as the EUV light source 106A. In the beam-shaping and illumination system 102, the EUV radiation 108A is focused and the desired operating wavelength is filtered out from the EUV radiation 108A. The EUV radiation 108A generated by the EUV light source 106A has a relatively low transmissivity through air, for which reason the beam-guiding spaces in the beam-shaping and illumination system 102 and in the projection system 104 are evacuated.

The beam-shaping and illumination system 102 illustrated in FIG. 1A has five mirrors 110, 112, 114, 116, 118. After passing through the beam-shaping and illumination system 102, the EUV radiation 108A is guided onto a photomask (reticle) 120. The photomask 120 is likewise formed as a reflective optical element and may be arranged outside the systems 102, 104. Furthermore, the EUV radiation 108A may be directed onto the photomask 120 via a mirror 122. The photomask 120 has a structure which is imaged onto a wafer 124 or the like in a reduced fashion via the projection system 104.

The projection system 104 (also referred to as a projection lens) has six mirrors M1 to M6 for imaging the photomask 120 onto the wafer 124. In this case, individual mirrors M1 to M6 of the projection system 104 may be arranged symmetrically in relation to an optical axis 126 of the projection system 104. It should be noted that the number of mirrors M1 to M6 of the EUV lithography apparatus 100A is not restricted to the number shown. A greater or lesser number of mirrors M1 to M6 may also be provided. Furthermore, the mirrors M1 to M6 are generally curved on their front sides for beam shaping.

Furthermore, an actuator 134 is provided, which is configured to change a position of the mirror 118, for example. Such an actuator 134 can also be provided for other mirrors 110, 112, 114, 116 in the beam-shaping and illumination system 102. Alternatively or additionally, such an actuator 134 may be provided for at least one of the mirrors M1-M6. A sensor 136 is provided, for example, which is configured to capture a position of the mirror 118. Such a sensor 136 can also be provided for other mirrors 110, 112, 114, 116 in the beam-shaping and illumination system 102. Alternatively or additionally, such a sensor 136 may be provided for at least one of the mirrors M1-M6. A multiplicity of such sensors 136 can also be provided.

FIG. 1B shows a schematic view of a DUV lithography apparatus 100B, which includes a beam-shaping and illumination system 102 and a projection system 104. In this case, DUV stands for “deep ultraviolet” and denotes a wavelength of the working light of between 30 nm and 250 nm. As has already been described with reference to FIG. 1A, the beam-shaping and illumination system 102 and the projection system 104 may be arranged in a vacuum housing and/or be surrounded by a machine room with corresponding drive apparatuses.

The DUV lithography apparatus 100B has a DUV light source 106B. By way of example, an ArF excimer laser that emits radiation 108B in the DUV range at 193 nm, for example, can be provided as the DUV light source 106B.

The beam-shaping and illumination system 102 illustrated in FIG. 1B guides the DUV radiation 108B onto a photomask 120. The photomask 120 is formed as a transmissive optical element and may be arranged outside the systems 102, 104. The photomask 120 has a structure which is imaged onto a wafer 124 or the like in a reduced fashion via the projection system 104.

The projection system 104 has multiple lens elements 128 and/or mirrors 130 for imaging the photomask 120 onto the wafer 124. In this case, individual lens elements 128 and/or mirrors 130 of the projection system 104 may be arranged symmetrically in relation to an optical axis 126 of the projection system 104. It should be noted that the number of lens elements 128 and mirrors 130 of the DUV lithography apparatus 100B is not restricted to the number shown. A greater or lesser number of lens elements 128 and/or mirrors 130 can also be provided. Furthermore, the mirrors 130 are generally curved on their front sides for beam shaping. The actuator 134 (see FIG. 1A) may be provided to change a position of the lens elements 128 and/or mirrors 130. For example, the sensor 136 (see FIG. 1A) is provided, which is configured to capture a position of the lens elements 128 and/or mirrors 130.

An air gap between the last lens element 128 and the wafer 124 can be replaced by a liquid medium 132 having a refractive index of >1. The liquid medium 132 may be for example high-purity water. Such a setup is also referred to as immersion lithography and has an increased photolithographic resolution. The medium 132 can also be referred to as an immersion liquid.

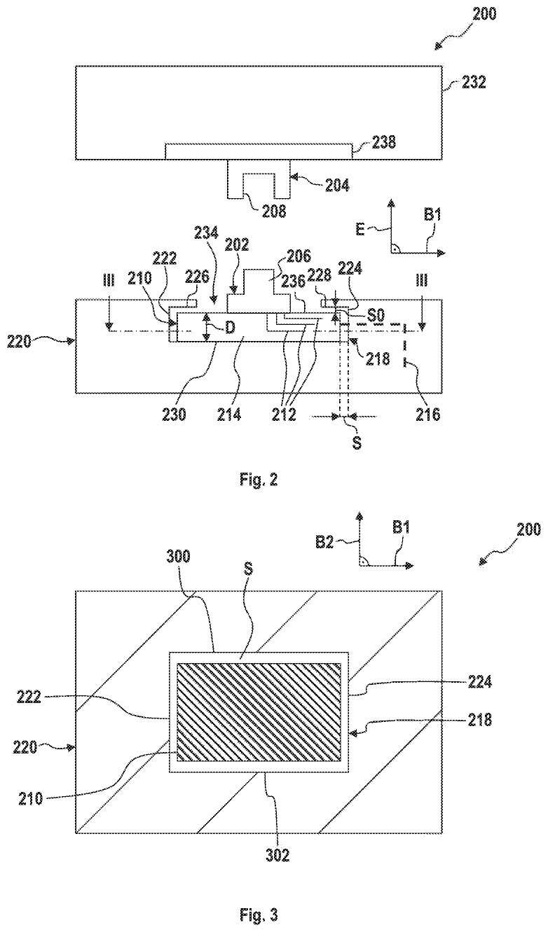

FIG. 2 shows a connector arrangement 200 for the lithography apparatus 100A, 100B (see FIGS. 1A and 1B). The connector arrangement 200 includes a connector element 202 (here also referred to as the first connector element), a connector element 204 (here also referred to as the second connector element), which can be plugged together with the connector element 202 in an insertion direction E to form an electrical connection. Optionally, the connector element 202 includes a connector 206 and the connector element 204 includes an associated socket 208.

In addition, a carrier element 210 is provided, which carries the connector element 202. The carrier element 210 and the connector element 202 are rigidly connected to one another. The carrier element 210 can be a printed circuit board, which includes conductor tracks 212 which are embedded in an insulating material 214 or mounted thereto. The material 214 may include a fiberglass composite. The carrier element 210 can also carry electronic components (not shown).

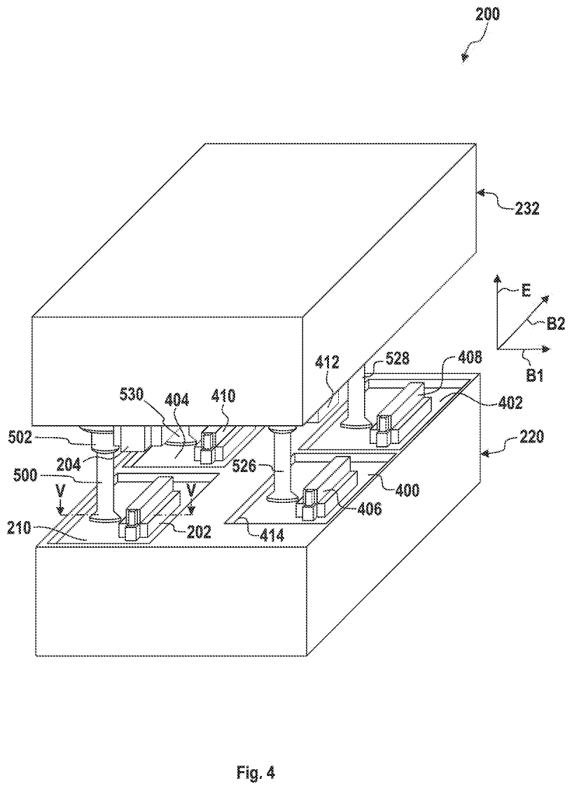

The carrier element 210 can have a two-dimensional form and has a thickness D of between 1.5 and 4 mm, for example 2 and 3 mm. Furthermore, an electrical line 216, for example a flexible cable and/or a rigid-flex-rigid connection (indicated by dashed lines) can be connected to the carrier element 210, which connects the carrier element 210 to, for example, a further carrier element 400, 402, 404 (see FIG. 4), an actuator 134 (see FIG. 1A), a sensor 136 (see FIG. 1A) or another electronic unit (not shown) of the lithography apparatus 100A, 100B (see FIGS. 1A and B).

The connector arrangement 200 additionally includes a receptacle 218, in which the carrier element 210 is accommodated so that it is movable in a movement direction B1 perpendicular to the insertion direction E in order to bring about tolerance compensation when the connector elements 202, 204 are plugged together. The receptacle 218 is provided as a cavity in a housing element 220 (also referred to herein as the first housing element). The carrier element 210 is accommodated in the receptacle 218 in such a way that a gap S is provided in the movement direction B1, which gap defines and delimits movability in the movement direction B1.

For example, a maximum gap S in the movement direction B1 (i.e., when the carrier element 210 rests against a side wall 222 of the receptacle 218) is between 0.1 and 15 mm, for example 1 and 5 mm. This can be referred to as floating support, for example. The receptacle 218 includes opposite side walls 222, 224, which delimit the movement of the carrier element 210 in the movement direction B1. The receptacle 218 furthermore includes walls 226, 228 that run perpendicularly to the side walls 222, 224 and prevent movement of the carrier element 210 relative to the receptacle 218 in the insertion direction E.

For example, a small clearance S0 is provided between the walls 226, 228 and the carrier element 210, for example a top side 236 of the carrier element 210, in order to prevent the carrier element 210 from becoming jammed in the receptacle 218. The clearance S0 can be between 0.05 and 2 mm, for example between 0.1 and 1.5 mm. The carrier element 210 can rest against a bottom 230 of the housing element 220, for example with a frictional connection. The carrier element 210 is accommodated within the receptacle 218 with a form-fitting connection.

The connector arrangement 200 further includes a housing element 232 (here also referred to as the second housing element) to which the connector element 204 is connected, for example indirectly. The connector element 204 can be connected to a printed circuit board 238, which is for example screwed onto the housing element 232. The connector element 204 can, for example, also be connected to the printed circuit board 238 merely via lines 1106 (see FIG. 11), for example flexible cables. For example, the connector element 204 protrudes from or out of the housing element 232. The housing element 220 includes an opening 234 to the receptacle 218 from which the connector element 202 protrudes. For example, multiple connector elements 204 may be connected to the printed circuit board 238. The printed circuit board 238 can be formed, for example, as a rigid-flex-rigid printed circuit board or a rigid printed circuit board.

For example, the connector element 202 includes a 10-400, for example 80-300, pin connector, and the connector element 204 includes a 10-400, for example 80-300, pin socket. The connector element 202 can be interchangeable with the connector element 204.

FIG. 3 shows section from FIG. 2. The gap S is formed as an annular gap which surrounds the carrier element 210. Merely by way of example, the carrier element 210 is shown as being rectangular in section. The carrier element 210 can have any shape and, for example, be L-shaped, trapezoidal or round. The annular shape of the gap S has the advantage that a movement of the carrier element 210 in a further movement direction B2, which is perpendicular to the insertion direction E and perpendicular to the movement direction B1, is also possible in order to bring about tolerance compensation when plugging the connector elements 202, 204 together.

The receptacle 218 includes side walls 300, 302, which delimit a movement of the carrier element 210 in the movement direction B2. For example, a maximum gap S in the movement direction B2 (i.e., when the carrier element 210 rests against the side wall 302 of the receptacle 218) is between 0.1 and 15 mm, for example 1 and 5 mm.

FIG. 4 shows a schematic perspective view of an embodiment of the connector arrangement 200. The latter additionally includes a connector element 406 (also referred to as the third connector element here), a connector element 412 (also referred to as the fourth connector element here), which can be plugged together with the connector element 406 in the insertion direction E to form an electrical connection, a carrier element 400 (here also referred to as the further carrier element), which carries the connector element 406, and a receptacle 414 (here also referred to as the further receptacle), in which the carrier element 400 is accommodated so as to be movable perpendicularly to the insertion direction E in order to bring about tolerance compensation when the connector elements 406, 412 are plugged together. The receptacle 414 is provided in the housing element 220. The connector element 412 is directly or indirectly connected to the housing element 232.

Two further carrier elements 402, 404, on which connector elements 408, 410 are mounted, are accommodated in the housing element 220. The connector elements 202, 406, 408, 410 are here arranged at a distance from one another. The carrier elements 400, 402, 404 are formed like the carrier element 210 and are correspondingly movably accommodated in receptacles (not shown) of the housing element 220.

Furthermore, connector elements (not shown), which can be plugged together with the connector elements 408, 410 in the insertion direction E and are thus formed as corresponding mating connectors, are formed on the housing element 232. Alternatively, instead of 4, it could also be possible to provide 2, 3, 5 or 6 carrier elements and connector elements with the housing element 220 and a corresponding number of connector elements with the housing element 232. For example, the carrier elements 210, 400, 402, 404 are connected to one another with the aid of cables (not shown), for example flex cables.

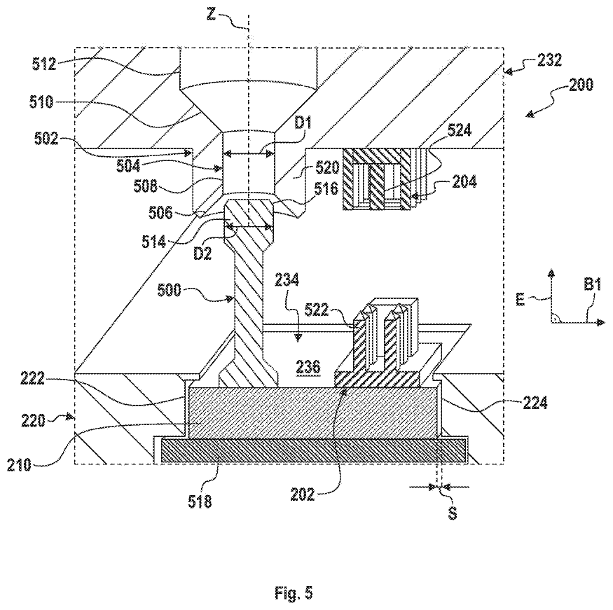

FIG. 5 shows section V-V from FIG. 4. In contrast to FIG. 2, the carrier element 210 rests on a part 518, which is for example an electronic component, mechanical component, or an electromechanical component and is provided at least partially in the housing element 220. The part 518 may be included by the actuator 134 (see FIG. 1A). The connector arrangement 200 includes a centering element 500 (here also referred to as the first centering element), which is directly or indirectly rigidly connected to the carrier element 210. Furthermore, a centering element 502 (here also referred to as the second centering element) is provided on the housing element 232.

The centering elements 500, 502 interact in such a way that the connector element 202 and the connector element 204 are aligned with one another with a precise fit when they are plugged together in the insertion direction E. The centering element 500 is provided next to the first connector element 202, extends beyond the connector element 202 in the insertion direction E, and is connected to the connector element 202 via the carrier element 210. The centering element 500 is formed, for example, as a centering pin, which is connected to the upper side 236 of the carrier element 210, for example with a materially bonded connection (e.g. via an adhesive bond). For example, the centering element 500 is screwed to the carrier element 210. Alternatively, the centering element 500 could be formed integrally with the carrier element 210.

The centering element 502 includes a receiving element 504, which is configured to accommodate the centering element 500 in order to bring about centering. Corresponding centering elements 526, 528, 530 can also be provided with the carrier elements 400, 402, 404. The centering element 502 can alternatively be integrated into the housing element 232 or be provided as a separate part which is connected to the housing element 232.

The receiving element 504 is formed as a cavity, which includes a frustoconical section 506 and, adjoining it, a cylindrical section 508. The section 508 is adjoined by a further frustoconical section 510, which in turn is adjoined by a cylindrical section 512. The frustoconical section 506 acts as an insertion bevel to center the centering element 500 with respect to a centering axis Z, which is formed for example as the axis of rotational symmetry of the receiving element 504. The section 506 tapers in the insertion direction E. The section 510 widens in the insertion direction E.

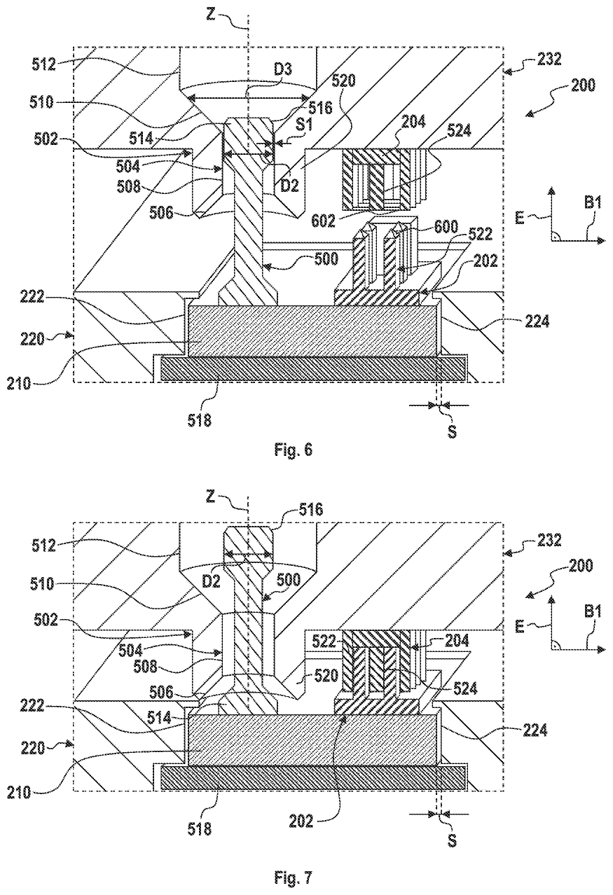

The centering element 500 includes a guide section 514. which is provided as a thickening and can form one end of the centering element 500. The section 508 has a width D1 (for example, diameter) that is slightly greater than a width D2 (for example, diameter) of the guide section 514, as a result of which there is a loose fit when the guide section 514 is situated within the section 508 (see FIG. 6). The guide section 514 includes, for example, an insertion bevel 516, which interacts with the receiving element 504 to align the centering element 500 with respect to the centering axis Z.

The centering element 502 can include a tubular section 520, which protrudes downwards from the housing element 232 counter to the insertion direction E and which includes the section 506 and at least partially the section 508. In addition, the connector element 202 includes a plurality of pins 522. The connector element 204 includes a multiplicity of sockets 524 corresponding to the pins 522.

As shown in FIG. 5, the centering element 500 is located in the section 506, which the centering element 500 passes first when one of the housing elements 220, 232 is moved in the insertion direction E toward the other one of the housing elements 220, 232. If the centering element 500 is not centrically aligned with the centering axis Z, the insertion bevel 516 presses against the section 506 and causes the centering element 500 to move in the movement direction B1, B2 due to a wedge effect.

Since the carrier element 210 is provided so as to be movable and is rigidly connected to the centering element 500, the carrier element 210 together with the connector element 202 also moves in the movement direction B1, B2. FIGS. 6 and 7 show how the guide section 514 is inserted further and further into the receiving element 504 until the connector elements 202, 204 are fully connected to one another.

In contrast to FIG. 5, FIG. 6 shows that the guide section 514 has been guided further into the receiving element 504 and is situated in the section 508. A clearance S1 is provided between the guide section 514 and the section 508. The clearance S1 is provided in such a way that an insertion bevel 600 of the connector element 202, for example of the pin 522, corresponds in the insertion direction E to an opening edge 602 of the connector element 204, for example of the socket 524, when the guide section 514 rests against a wall of the section 508.

A two-stage centering can thus be provided, in which, in a first stage, pre-centering can take place with the aid of the centering elements 500, 502 and, in a second stage, final centering can take place with the aid of the insertion bevels 600 of the connector element 522 and of the opening edge 602 of the connector element 204 when plugging in the connector elements 202, 204.

When the housing elements 220, 232 are further brought together in the insertion direction E, the guide section 514 leaves the section 508 and moves directly into the section 510, which has an expanding width D3, for example diameter. The width D3 is greater than the width D1 (see FIG. 5) so that the guide section 514 is no longer guided when it leaves the section 508. At the same time, the connector elements 202, 204 begin to engage in one another, with the result that centering takes place via the connector elements 202, 204 themselves and further guidance through the section 508 is not necessary. This also has the advantage that an overdetermined system is avoided.

In contrast to FIG. 6, FIG. 7 shows that the connector elements 202, 204 are completely plugged into one another. An electrical connection between the connector elements 202, 204 is formed in this way.

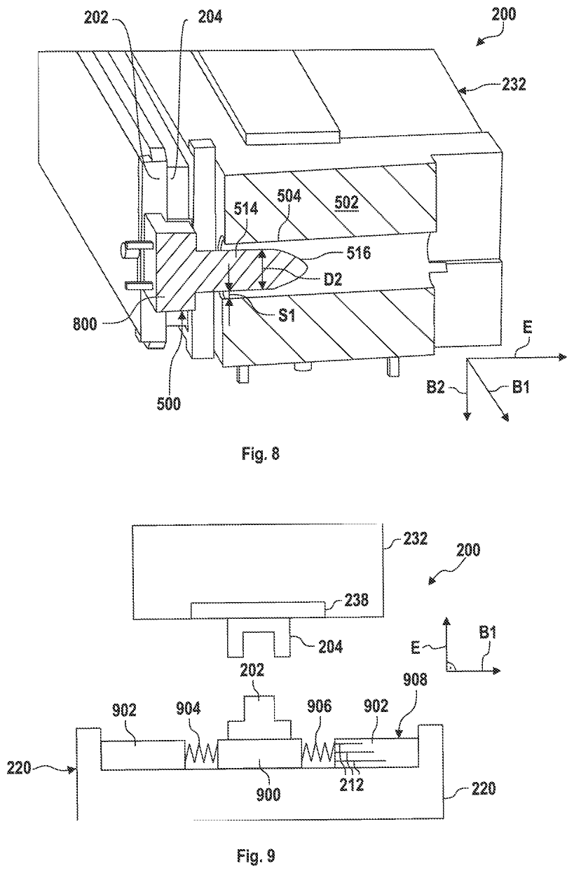

FIG. 8 shows an embodiment of the connector arrangement 200 in the plugged-in state of the connector elements 202, 204. In contrast to the embodiment from FIGS. 5 to 7, the centering element 500 is connected directly to the connector element 202, is formed integrally therewith or is at least in contact therewith. The centering element 500 is arranged next to the connector element 500 as viewed in the movement direction B1.

The centering element 500 includes a base section 800, which is connected to the connector element 202 and is adjoined by the guide section 514, which is cylindrical in shape and includes a tip that forms the insertion bevels 516. The receiving element 504 is formed as a cavity, for example a cylindrical cavity. In this exemplary embodiment, the clearance S1 can, for example, be larger than in the exemplary embodiment in FIG. 5. For example, a larger tolerance compensation can then also be compensated for by the connector elements 202, 204. This has the advantage that the centering elements 500, 502 can be simplified.

FIG. 9 shows an embodiment of the connector assembly 200. The connector assembly includes the connector element 202, the connector element 204, a printed circuit board section 900 (here also referred to as the first printed circuit board section), on which the connector element 202 is mounted, and a printed circuit board section 902 (here also referred to as the second printed circuit board section), in which the printed circuit board section 900 is attached so as to be movable perpendicularly to the insertion direction E in order to bring about tolerance compensation when the connector elements 202, 204 are plugged together. The connector element 204 can be connected to the printed circuit board 238. For example, multiple connector elements can be connected to the printed circuit board 238.

For example, the printed circuit board 238 is formed like the printed circuit board sections 900, 902 (i.e., movable).

For example, the printed circuit board section 902 is mounted in the housing section 220 in such a way that it does not move when the connector elements 202, 204 are plugged together. The printed circuit board section 902 can be screwed to the housing section 232. When the connector elements 202, 204 are plugged together, the printed circuit board section 900 together with the connector element 202 moves in the movement direction B1, B2 relative to the printed circuit board section 902 and the housing section 220 in order to bring about tolerance compensation.

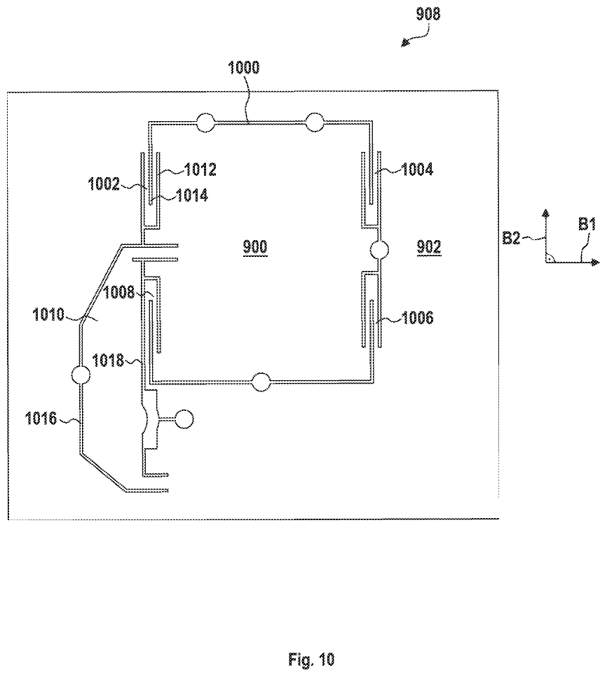

For example, the printed circuit board section 900 and the printed circuit board section 902 are formed integrally with one another. The printed circuit board sections can be connected to one another via at least one spring element 904, 906. For example, the spring element 904, 906 is formed as a flexure 1000, 1002, 1004, 1006, 1008 (see FIG. 10). The printed circuit board sections 900, 902 can form a printed circuit board 908, which is divided into two printed circuit board sections 900, 902. The printed circuit board section 902 includes the conductor tracks 212, which are electrically connected to the connector element 202. For example, the connector element 202 can be brought into direct contact with the conductor tracks 212.

Alternatively, the connector element 202 can be brought into contact with conductor tracks (not shown) of the printed circuit board section 900, which in turn are electrically connected to the conductor tracks 212. Furthermore, the conductor tracks 212 can extend through the spring element 904, 906 into the printed circuit board section 900 and be brought into contact with the connector element 202. Furthermore, centering elements, as described for FIGS. 4 to 8, can be provided for this exemplary embodiment.

FIG. 10 shows a top view of an embodiment of the printed circuit board 908. The printed circuit board 908 has material weakenings 1000, which are formed in such a way that at least one flexure 1002, 1004, 1006, 1008, 1010 is formed between the printed circuit board sections 900, 902. For example, a plurality of flexures 1002, 1004, 1006, 1008, 1010 can be formed as spring elements 904, 906. These can be formed integrally with the printed circuit board sections 900, 902 and therefore consist for example of the same material.

The material weakenings 1000 can be introduced, for example, with the aid of a separating process, for example lasering or milling. The material weakenings 1000 can be formed as gaps or cutouts, which can extend over an entire thickness of the printed circuit is board sections 900, 902. For example, material weakenings 1012, 1014 are introduced into the printed circuit board 908 in such a way that a flexure 1002 is formed in the shape of a U. Furthermore, a further U-shaped flexure 1004 can be provided opposite the flexure 1002.

Two further U-shaped flexures 1006, 1008 can be provided mirror-symmetrically to the flexures 1002, 1004. Furthermore, for example, material weakenings 1016, 1018 are provided in such a way that a trapezoidal flexure 1010 is formed. The flexures 1002, 1004, 1006, 1008, 1010 are configured to allow an elastic movement of the printed circuit board section 900 relative to the printed circuit board section 902. The flexures 1002, 1004, 1006, 1008, 1010 can also be L-shaped, curved, W-shaped or I-shaped, for example.

FIG. 11 shows a system 1100 for the lithography apparatus 100A, 100B (see FIGS. 1 and 2). The system 1100 includes the connector arrangement 200 and the actuator 134, which is electrically connected to the carrier section 210 or the printed circuit board section 902 and the connector element 202 via a multiplicity of lines 1104. The connector element 202 acts as an electronic interface of the actuator 134, which is connectable to the connector element 204. For example, the system 1100 includes an integrated circuit 1102, which is electrically connected to the connector element 204 via a multiplicity of lines 1106.

The actuator 134 can be screwed to the housing element 220. The connector element 204 acts as an electronic interface of the integrated circuit 1102 to the connector element 202. The circuit may include a processor 1108. Instead of an actuator 134, the system can also include 2, 3, 4 or more actuators, which are brought into contact with the circuit 1102 via the connector elements 202, 204, 406, 408, 410, 412 (see FIG. 4).

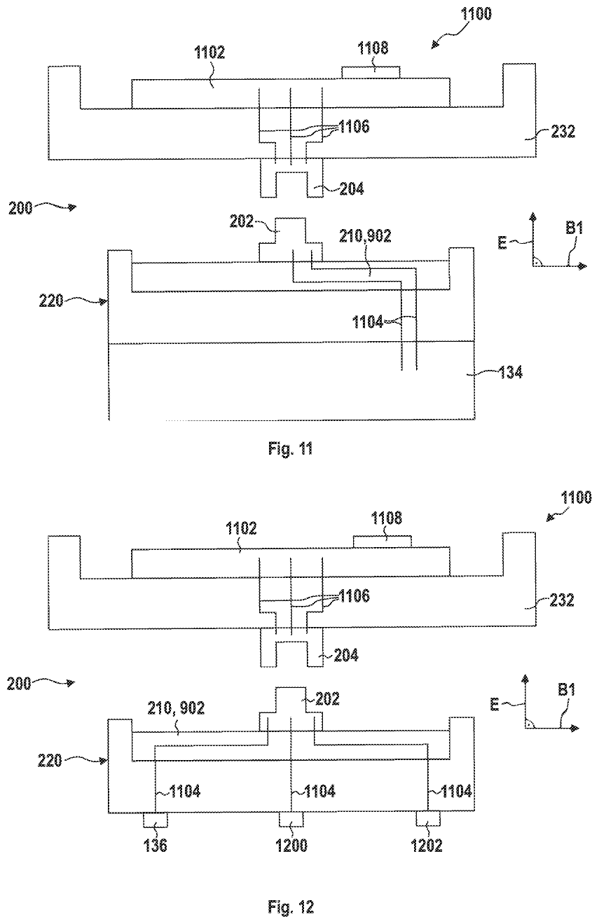

FIG. 12 shows, in contrast to FIG. 11, that the system 1100 has, instead of the actuator 134, sensors 136, 1200, 1202, which are configured, for example, to capture a position of a mirror 110, 112, 114, 116, 118, M1, M2, M3, M4, M5, M6 of the lithography apparatus 100A, 100B. It goes without saying that such a system 1100 can include a multiplicity of connector elements, the actuator 134 from FIG. 11, and the sensors 136, 1200, 1202 from FIG. 12 in combination.

Although the present disclosure has been described on the basis of exemplary embodiments, it can be modified in various ways.

### LIST OF REFERENCE SIGNS

100A EUV lithography apparatus
100B DUV lithography apparatus
102 Beam-shaping and illumination system
104 Projection system
106A EUV light source
106B DUV light source
108A EUV radiation
108B DUV radiation
110 Mirror
112 Mirror
114 Mirror
116 Mirror
118 Mirror
120 Photomask
122 Mirror
124 Wafer
126 Optical axis
128 Lens element
130 Mirror
132 Medium
134 Actuator
136 Sensor
200 Connector arrangement
202 Connector element
204 Connector element
206 Connector
208 Socket
210 Carrier element
212 Conductor tracks
214 Material
216 Line
218 Receptacle
220 Housing element
222 Side wall
224 Side wall
226 Side wall
228 Side wall
230 Bottom
232 Housing element
234 Opening
236 Upper side
238 Printed circuit board
300 Wall
302 Wall
400 Carrier element
402 Carrier element
404 Carrier element
406 Connector element
408 Connector element
410 Connector element
412 Connector element
414 Receptacle
500 Centering element
502 Centering element
504 Receiving element
506 Section
508 Section
510 Section
512 Section
514 Guide section
516 Insertion bevel
518 Part
520 Tubular section
522 Pin
524 Socket
526 Centering element
528 Centering element
530 Centering element
600 Insertion bevel
602 Opening edge
800 Base section
900 Printed circuit board section
902 Printed circuit board section
904 Spring element
906 Spring element
908 Printed circuit board
1000 Material weakening
1002 Flexure
1004 Flexure
1006 Flexure
1008 Flexure
1010 Flexure
1012 Material weakening
1014 Material weakening
1100 System
1102 Circuit
1104 Line
1106 Line
1108 Processor
1200 Sensor
1202 Sensor
B1 Movement direction
B2 Movement direction
E Insertion direction
D Thickness
D1 Width
D2 Width
D3 Width
M1 Mirror
M2 Mirror
M3 Mirror
M4 Mirror
M5 Mirror
M6 Mirror
S Gap
S0 Clearance
S1 Clearance
Z Centering axis

What is claimed is:

1. A connector arrangement, comprising:
a first connector element;
a second connector element configured to be plugged together with the first connector element in an insertion direction to define an electrical connection;
a first printed circuit board section on which the first connector element is mounted; and
a second printed circuit board section on which the first printed circuit board section is mounted so as to be movable perpendicularly to the insertion direction to provide tolerance compensation when the first and second connector elements are plugged together.

2. The connector arrangement of claim 1, wherein the first and second connector elements are plugged together.

3. The connector arrangement of claim 2, wherein the first and second printed circuit board sections are integral with one another.

4. The connector arrangement of claim 2, further comprising a flexure connecting the first and second printed circuit board sections.

5. The connector arrangement of claim 1, wherein the first and second printed circuit board sections are integral with one another.

6. The connector arrangement of claim 1, further comprising a flexure connecting the first and second printed circuit board sections.

7. An apparatus, comprising:
a connector arrangement according to claim 1, wherein the apparatus is a lithography apparatus.

8. The apparatus of claim 7, wherein the first and second connector elements are plugged together.

9. A system, comprising:
a first connector element;
a carrier section supporting the first connector element;
a second connector element configured to be plugged together with the first connector element in an insertion direction to define an electrical connection;
a first printed circuit board section on which the first connector element is mounted;
a second printed circuit board section on which the first printed circuit board section is mounted so as to be movable perpendicularly to the insertion direction to provide tolerance compensation when the first and second connector elements are plugged together; and
an actuator electrically connected to a member selected from the group consisting of the carrier section and the first connector element.

10. The system of claim 8, wherein the actuator is electrically connected to the carrier section.

11. The system of claim 8, wherein the actuator is electrically connected to the first connector element.

12. The system of claim 8, further comprising a sensor electrically connected to the carrier section.

13. The system of claim 8, further comprising a sensor electrically connected to the first connector element.

14. The system of claim 8, further comprising an integrated circuit electrically connected to the second connector element.

15. An apparatus, comprising:
a system according to claim 10, wherein the apparatus is a lithography apparatus.

16. A system, comprising:
a first connector element;
a carrier section supporting the first connector element;
a second connector element configured to be plugged together with the first connector element in an insertion direction to define an electrical connection;
a first printed circuit board section on which the first connector element is mounted;
a second printed circuit board section on which the first printed circuit board section is mounted so as to be movable perpendicularly to the insertion direction to provide tolerance compensation when the first and second connector elements are plugged together; and
a sensor electrically connected to a member selected from the group consisting of the carrier section and the first connector element.

17. The system of claim 16, wherein the sensor is electrically connected to the carrier section.

18. The system of claim 16, wherein the sensor is electrically connected to the first connector element.

19. The system of claim 16, further comprising an integrated circuit electrically connected to the second connector element.

20. An apparatus, comprising:
a system according to claim 16, wherein the apparatus is a lithography apparatus.
